(19) United States
(12) Patent Application Publication
(10) Pub. No.: US 2019/0207646 A1
(43) Pub. Date: Jul. 4, 2019

(54) PULSE POSITION MODULATION CIRCUIT

(71) Applicant: FUJITSU LIMITED, Kawasaki-shi (JP)

(72) Inventors: Ikuo SOGA, Isehara (JP); Kazuaki Oishi, Yokohama (JP); Hiroshi Matsumura, Atsugi (JP); Yoichi Kawano, Setagaya (JP); Yasuhiro Nakasha, Hadano (JP)

(73) Assignee: FUJITSU LIMITED, Kawasaki-shi (JP)

(21) Appl. No.: 16/298,486

(22) Filed: Mar. 11, 2019

Related U.S. Application Data
(63) Continuation of application No. PCT/JP2018/006037, filed on Feb. 20, 2018.

(30) Foreign Application Priority Data
Mar. 28, 2017 (JP) 2017-063391

(51) Int. Cl. H04B 1/717; H04B 1/7163; H04L 25/49; H03K 5/135; H03K 5/133

(52) U.S. Cl. CPC H04B 1/7174; H04B 1/71637; H03K 5/133; H03K 5/135; H04L 25/4902

(57) ABSTRACT

A pulse position modulation circuit includes a delay path that includes a plurality of delay devices coupled in series with each other, a clock being passed through the plurality of delay devices, and a switching circuit that changes a time by which the clock is delayed in each of the plurality of delay devices according to input data.

### CROSS-REFERENCE TO RELATED APPLICATION

This application is a continuation application of International Application PCT/JP2018/006037 filed on Feb. 20, 2018 and designated the U.S., the entire contents of which are incorporated herein by reference. The International Application PCT/JP2018/006037 is based upon and claims the benefit of priority of the prior Japanese Patent Application No. 2017-063391, filed on Mar. 28, 2017, the entire contents of which are incorporated herein by reference.

### FIELD

The embodiments discussed herein are related to a pulse position modulation (PPM) circuit.

### BACKGROUND

There is a pulse position modulation circuit which transmits data by changing the temporal position of a pulse.

The pulse position modulation circuit generates a plurality of different delay times according to input data by using a plurality of delay devices. However, when the transmission rate of the data is increased, variation in the generated delay times may become intolerable.

The followings are reference documents.

### [Document 1] Japanese Laid-open Patent Publication No. 2016-086309,

### [Document 2] Japanese Laid-open Patent Publication No. 2005-198236, and

### [Document 3] Japanese Laid-open Patent Publication No. 2004-032752.

### SUMMARY

According to an aspect of the embodiments, a pulse position modulation circuit includes a delay path that includes a plurality of delay devices coupled in series with each other, a clock being passed through the plurality of delay devices, and a switching circuit that changes a time by which the clock is delayed in each of the plurality of delay devices according to input data.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a configuration of an impulse radio communication system;

FIG. 2 is a diagram illustrating an example of a configuration of a PPM circuit (comparative example);

FIG. 3 is a timing diagram illustrating an example of differences in a data signal output from a PPM circuit;

FIG. 4 is a diagram illustrating an example of delay time variation in a PPM circuit (comparative example);

FIG. 5 is a diagram illustrating an example of a configuration of a PPM circuit (embodiment);

FIG. 6 is a diagram illustrating an example of variations in a delay time generated by a delay circuit;

FIG. 7 is a diagram illustrating an example of delay device characteristics;

FIG. 8 is a diagram illustrating an example of configuration of a delay device;

FIG. 9 is a diagram illustrating an example of delay time variations in the comparative example and the embodiment; and

FIG. 10 is a diagram illustrating another example of configuration of delay devices.

### DESCRIPTION OF EMBODIMENTS

Description will hereinafter be made of embodiments of a pulse position modulation circuit according to the present disclosure.

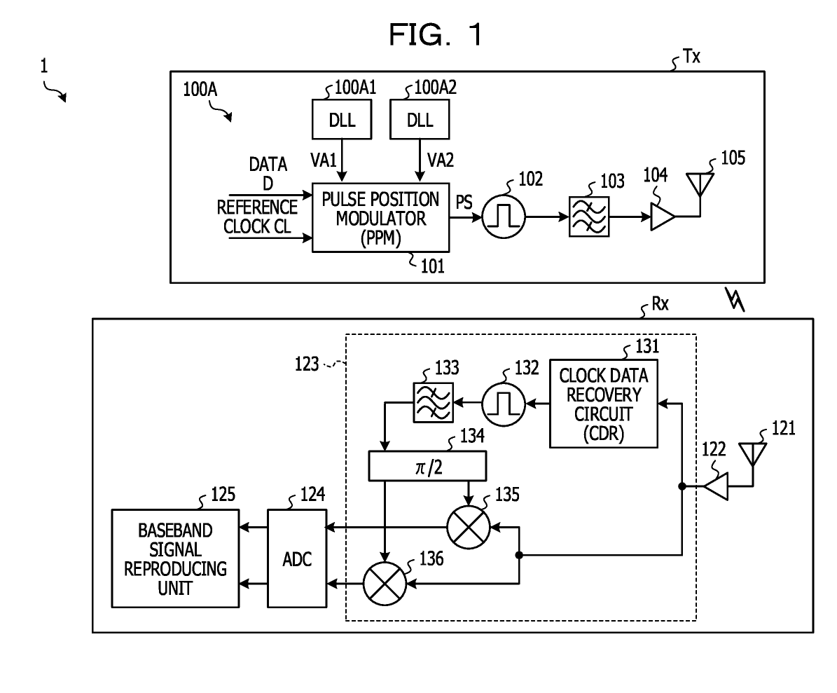

FIG. 1 is a diagram illustrating an example of a configuration of an impulse radio communication system in which a pulse position modulation circuit is used. An impulse radio communication system 1 illustrated in FIG. 1 performs radio communication by an impulse method using radio frequency (RF) pulses as a transmission medium. The impulse radio communication system 1 includes an impulse transmitter Tx and an impulse receiver Rx.

The impulse transmitter Tx includes a delay locked loop (DLL) circuit 100, a PPM circuit 101, a pulse generator 102, a band-pass filter 103, a transmitting amplifier 104, and a transmitting antenna 105.

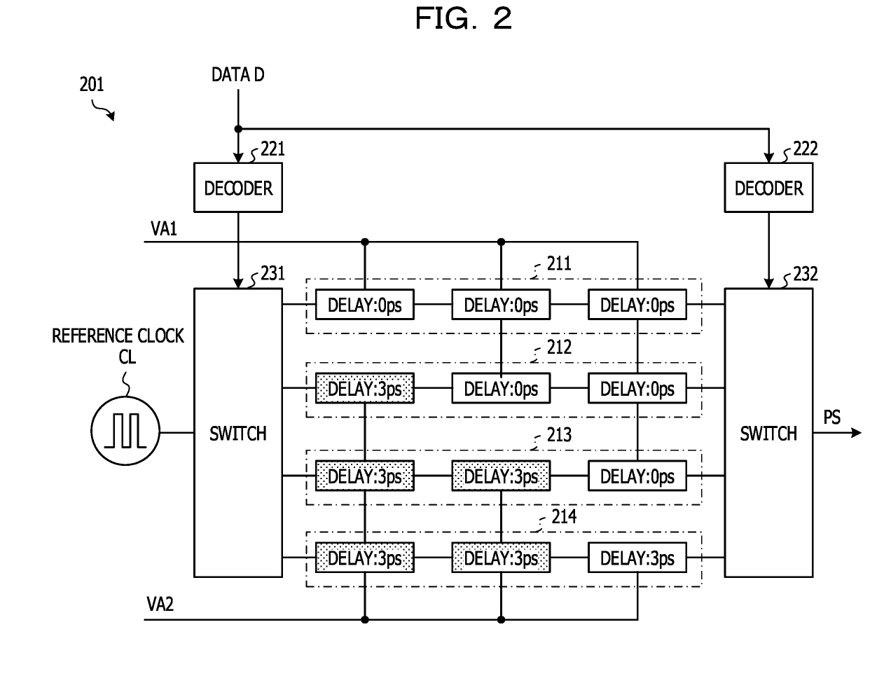

The DLL circuit 100 supplies the PPM circuit 101 with a control signal that controls a delay time by which a reference clock CL is delayed. The reference clock CL is an example of a clock. The DLL circuit 100 in a mode illustrated in FIG. 2 includes DLL units 100A1 and 100A2 that generate two kinds of control voltages VA1 and VA2. The control voltage VA1 generated by the DLL unit 100A1 and the control voltage VA2 generated by the DLL unit 100A2 are each an example of a control signal that controls a delay time by which the reference clock CL is delayed.

The PPM circuit 101 generates a pulsed modulated signal PS by delaying the reference clock CL by a delay time corresponding to input data D. The PPM circuit 101 outputs the modulated signal PS to the pulse generator 102. The input data D is an example of data input to the pulse position modulation circuit 101.

The pulse generator 102 generates a pulse of a given pulse width when detecting an edge (for example, a rising edge) of the modulated signal PS in a time slot. The band-pass filter 103 outputs a filter passed pulse (for example, a millimeter-wave pulse) by subjecting the pulse generated by the pulse generator 102 to filtering that passes only a given pass frequency band. The given pass frequency band, for example, has a pass lower limit frequency of 80 GHz, a pass upper limit frequency of 90 GHz, and a pass frequency bandwidth of 10 (=90−80) GHz.

The output of the band-pass filter 103 is input to the transmitting amplifier 104. For example, the millimeter-wave pulse is amplified by the transmitting amplifier 104, and thereby a transmission signal (impulse signal) is radio-transmitted via the transmitting antenna 105. The transmission signal transmits data “1” or “0” corresponding to the presence or absence of the millimeter-wave pulse.

The impulse receiver Rx includes a receiving antenna 121, a receiving amplifier 122, a detector 123, an analog-to-digital converter (ADC) 124, and a baseband signal reproducing unit 125.

The receiving amplifier 122 amplifies a received signal (impulse signal) radio-received via the receiving antenna 121, and outputs the received signal to the detector 123. The detector 123 detects an envelope of the received signal (millimeter-wave pulse) amplified by the receiving amplifier 122, and outputs the envelope of the received signal to the ADC 124.

The detector 123 includes a clock data recovery (CDR) circuit 131, a pulse generator 132, a band-pass filter 133, a first mixer 135, a second mixer 136, and a n/2 phase shifter 134.

The pulse generator 132 generates a local oscillating signal of a frequency (for example, 83.5 GHz) within the pass frequency band of the band-pass filter 103 of the impulse transmitter Tx based on the clock reconstructed by the CDR circuit 131.

The band-pass filter 133 has a pass frequency band characteristic similar to that of the band-pass filter 103 of the impulse transmitter Tx. The band-pass filter 133 generates a pulse signal corresponding to the local oscillating signal from the pulse generator 132.

The first mixer 135 performs detection by mixing the output signal of the receiving amplifier 122 with the pulse signal output by the band-pass filter 133. The second mixer 136 performs detection by mixing the output signal of the receiving amplifier 122 with a phase-shifted signal generated by the n/2 phase shifter 134 by phase-shifting the phase of the pulse signal output by the band-pass filter 133 by n/2. Intermediate frequency (IF) signals are thereby obtained.

The local oscillating signals mixed by the first mixer 135 and the second mixer 136 are shifted in phase from each other by n/2 (for example, 3 ps). A Q-signal as one of the IF signals is output from the first mixer 135. An I-signal as one of the IF signals is output from the second mixer 136.

The ADC 124 converts the analog Q-signal and the analog I-signal into digital data. The baseband signal reproducing unit 125 detects the phase of the impulse signal received by the receiving antenna 121 from the digital Q-signal and the digital I-signal. The baseband signal reproducing unit 125 reproduces data from the detected phase and the phase of the received clock.

It is to be noted that the impulse radio communication system is not limited to usage in a millimeter-wave band. For example, the impulse radio communication system is applicable to communication of a UWB (Ultra Wide Band; ultra-wide band radio) system including a micro-wave band and a quasi-millimeter wave band.

A PPM circuit (for example, the PPM circuit 101 described above) generates a plurality of different kinds of delay times according to input data by using a plurality of delay devices. A configuration as illustrated in FIG. 2, for example, is considered as a circuit that generates a plurality of different kinds of delay times according to the input data by using the plurality of delay devices.

FIG. 2 is a diagram illustrating a configuration of one comparative example of a PPM circuit. A PPM circuit 201 illustrated in FIG. 2 includes a plurality of kinds of delay paths 211 to 214 prepared in advance and decoders 221 and 222 that select which of the delay paths 211 to 214 to use according to the input data D.

The delay paths 211 to 214 each include three delay devices coupled in series with each other. The respective delay times of the following delay devices are set to 0 ps by the control voltage VA1: all of the delay devices within the delay path 211, delay devices in a second stage and a third stage from an input side within the delay path 212, and a delay device in a third stage from the input side within the delay path 213. The respective delay times of the following delay devices are set to 3 ps by the control voltage VA2: all of the delay devices within the delay path 214, delay devices in a first stage and a second stage from the input side within the delay path 213, and a delay device in a first stage from the input side within the delay path 212.

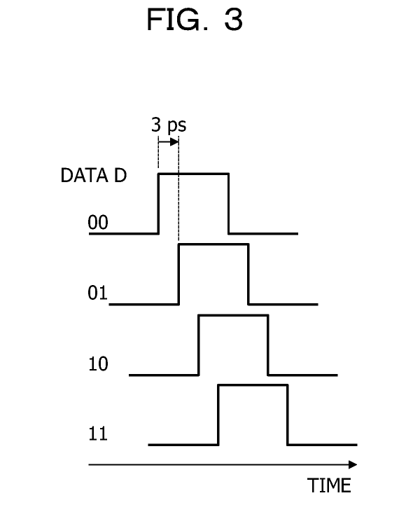

In a case where the input data D of 2 bits is “00,” the decoders 221 and 222 switch the path through which to pass the reference clock CL to the delay path 211 by switches 231 and 232. In a case where the input data D of 2 bits is “01,” the decoders 221 and 222 switch the path through which to pass the reference clock CL to the delay path 212 by the switches 231 and 232. In a case where the input data D of 2 bits is “10,” the decoders 221 and 222 switch the path through which to pass the reference clock CL to the delay path 213 by the switches 231 and 232. In a case where the input data D of 2 bits is “11,” the decoders 221 and 222 switch the path through which to pass the reference clock CL to the delay path 214 by the switches 231 and 232. For example, as illustrated in FIG. 3, the temporal position of the pulsed modulated signal PS changes according to the input data D.

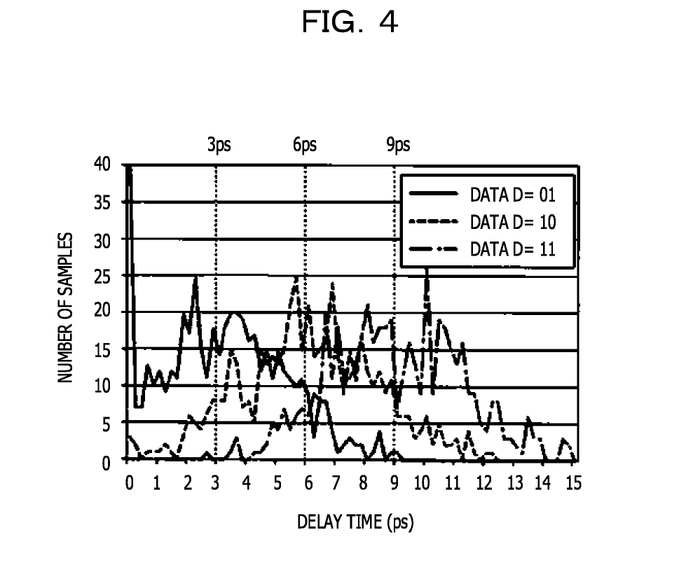

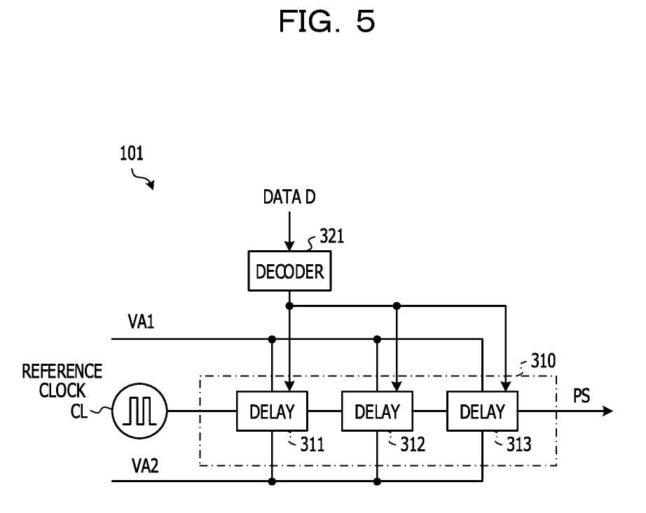

The circuit configuration illustrated in FIG. 2 may be adopted when delay time variations caused by individual difference variations in the delay paths are sufficiently small as compared with the generated delay times. However, as illustrated in FIG. 4, for example, when there is 6 ps (corresponding to 3 σ) or more of delay time variation caused by the individual difference variations in the delay paths, it is difficult to accurately generate a delay time shorter than a delay time corresponding to 3 σ. Accordingly, the present disclosure provides a PPM circuit illustrated in FIG. 5 in order to suppress the delay time variation.

FIG. 5 is a diagram illustrating an example of a configuration of a PPM circuit according to an embodiment of the present disclosure. A PPM circuit 101 illustrated in FIG. 5 includes a delay path 310 and a decoder 321.

The delay path 310 includes a plurality of delay devices (three delay devices in the case illustrated in FIGS. 5) 311, 312, and 313 coupled in series with each other. The delay path 310 includes the delay device 311 having the reference clock CL as an input thereto, the delay device 312 having an output of the delay device 311 as an input thereto, and the delay device 313 having an output of the delay device 312 as an input thereto. The modulated signal PS is output by passing the reference clock CL through the plurality of delay devices 311, 312, and 313. The decoder 321 is an example of a switching circuit that changes a delay time by which the reference clock CL is delayed in each of the plurality of delay devices 311, 312, and 313 according to the input data D.

As illustrated in FIG. 5, the delay devices 311, 312, and 313 are coupled in series with each other. Hence, even when the respective delay times of the delay devices 311, 312, and 313 vary, variation in the delay time of the whole of the delay path 310 may be suppressed. For example, in the mode of FIG. 2, delay time variation occurs at four positions (delay paths 211, 212, 213, and 214), whereas delay time variation occurs only at one position (delay path 310) in the mode of FIG. 5. Hence, according to the mode of FIG. 5, variation in the delay time of the whole of the delay path may be suppressed as compared with the mode of FIG. 2.

In FIG. 5, the decoder 321 changes a control voltage that controls a delay time by which the reference clock CL is delayed in each of the delay devices 311, 312, and 313 according to the input data D. It is thereby possible to adjust the respective delay times of the delay devices 311, 312, and 313 individually, and suppress variations in the delay time of the whole of the delay path 310.

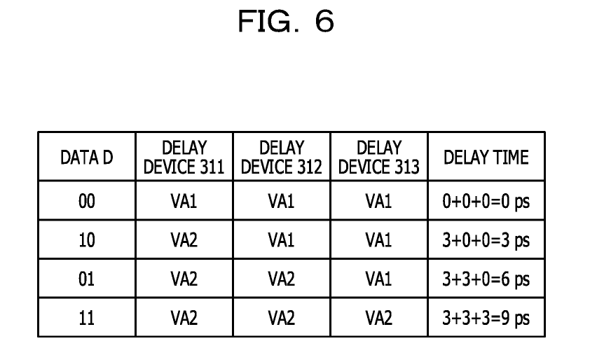

FIG. 6 is a diagram illustrating an example of variations in a delay time generated by a delay path. The decoder 321 selects control voltages that control the delay time by which the reference clock CL is delayed from the control voltages VA1 and VA2 according to the input data D.

In a case where the input data D of 2 bits is “00,” the decoder 321 sets the control voltages that control the respective delay times of the delay devices 311, 312, and 313 to the control voltage VA1, the control voltage VA1, and the control voltage VA1, respectively. In a case where the input data D of 2 bits is “01,” the decoder 321 sets the control voltages that control the respective delay times of the delay devices 311, 312, and 313 to the control voltage VA2, the control voltage VA1, and the control voltage VA1, respectively. In a case where the input data D of 2 bits is “10,” the decoder 321 sets the control voltages that control the respective delay times of the delay devices 311, 312, and 313 to the control voltage VA2, the control voltage VA2, and the control voltage VA1, respectively. In a case where the input data D of 2 bits is “11,” the decoder 321 sets the control voltages that control the respective delay times of the delay devices 311, 312, and 313 to the control voltage VA2, the control voltage VA2, and the control voltage VA2, respectively.

When the control voltages are thus set, the temporal position of the pulsed modulated signal PS changes in increments of 3 ps in accordance with the input data D.

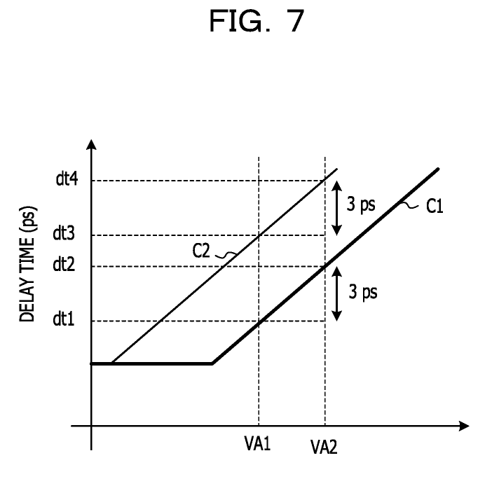

FIG. 7 is a diagram illustrating an example of delay device characteristics. The delay devices 311, 312, and 313 each have a mutually identical delay characteristic. C1 represents a typical delay characteristic of the delay devices. C2 represents a delay characteristic when variations of individual differences in the delay devices occur.

In a state in which the delay characteristic is C1, when the control voltage VA1 is selected as a voltage that controls the delay time, the delay time of each delay device is dt1. In the state in which the delay characteristic is C1, when the control voltage VA2 is selected as a voltage that controls the delay time, the delay time of each delay device is dt2. On the other hand, in a state in which the delay characteristic is C2, when the control voltage VA1 is selected as a voltage that controls the delay time, the delay time of each delay device is dt3. In the state in which the delay characteristic is C2, when the control voltage VA2 is selected as a voltage that controls the delay time, the delay time of each delay device is dt4.

However, the value of the control voltage VA1 and the value of the control voltage VA2 are set in advance such that a difference between the delay time when the control voltage VA1 is selected and the delay time when the control voltage VA2 is selected is a delay time desired to be generated in position modulation. Because a rate of change of the delay time with respect to the control voltage is substantially the same between C1 and C2, substantially the same delay time is obtained even when the delay characteristic of the delay device changes from C1 to C2 due to a characteristic variation as long as a difference between two control voltages (VA2−VA1) is the same. Hence, variations in delay time may be suppressed.

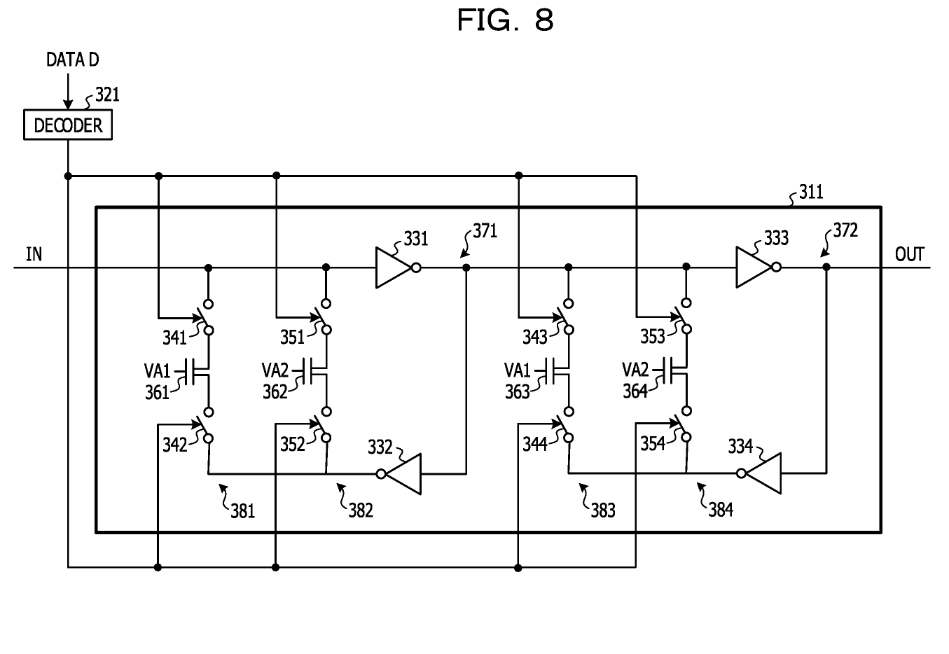

FIG. 8 is a diagram illustrating one concrete example of configuration of a delay device. FIG. 8 illustrates a configuration of the delay device 311. However, the other delay devices 312 and 313 each also have the same configuration as the delay device 311. The reference clock CL input from an input part IN of the delay device 311 is output from an output part OUT of the delay device 311.

The delay device 311 includes an even number of unit circuits 371 and 372 (two unit circuits 371 and 372 in the case illustrated in FIG. 8) coupled in series with each other. The delay device 311 includes the unit circuit 371 having the reference clock CL as an input thereto and the unit circuit 372 having an output of the unit circuit 371 as an input thereto. The reference clock CL output from the unit circuit 372 is input to a unit circuit in a first stage within the delay device 312 in a subsequent stage.

The unit circuit 371 includes an inverter 331, an inverter 332 having the output of the inverter 331 as an input thereto, and control paths 381 and 382 equal in number to the control voltages VA1 and VA2 (for example, two control paths). The control paths 381 and 382 are both coupled between an output of the inverter 332 and an input of the inverter 331. The inverters 331 and 332 each invert an input/output logic level.

The unit circuit 372 includes an inverter 333, an inverter 334 having the output of the inverter 333 as an input thereto, and control paths 383 and 384 equal in number to the control voltages VA1 and VA2 (for example, two control paths). The control paths 383 and 384 are both coupled between an output of the inverter 334 and an input of the inverter 333. The inverters 333 and 334 each invert an input/output logic level.

The decoder 321 selects a path that controls a time by which the reference clock CL is delayed according to the control voltages VA1 and VA2 from the control paths 381 to 384 according to the input data D.

The control path 381 to which the control voltage VA1 is applied includes interrupting parts 341 and 342 and a resistance part 361. The control path 383 to which the control voltage VA1 is applied includes interrupting parts 343 and 344 and a resistance part 363. The control path 382 to which the control voltage VA2 is applied includes interrupting parts 351 and 352 and a resistance part 362. The control path 384 to which the control voltage VA2 is applied includes interrupting parts 353 and 354 and a resistance part 364.

The interrupting parts 341 and 342 interrupt the coupling of the control path 381 between the output of the inverter 332 and the input of the inverter 331 based on a signal output from the decoder 321 according to the input data D. The interrupting parts 351 and 352 interrupt the coupling of the control path 382 between the output of the inverter 332 and the input of the inverter 331 based on a signal output from the decoder 321 according to the input data D. The interrupting parts 343 and 344 interrupt the coupling of the control path 383 between the output of the inverter 334 and the input of the inverter 333 based on a signal output from the decoder 321 according to the input data D. The interrupting parts 353 and 354 interrupt the coupling of the control path 384 between the output of the inverter 334 and the input of the inverter 333 based on a signal output from the decoder 321 according to the input data D. A transfer gate using a transistor is cited as a concrete example of each interrupting part.

The control voltage VA1 is applied to the resistance part 361. When the interrupting parts 341 and 342 in front of and in the rear of the resistance part 361 are both in an on state, the resistance value of the resistance part 361 is a value corresponding to the control voltage VA1 (state in which the control voltage VA1 is selected). Similarly, the control voltage VA1 is applied to the resistance part 363. When the interrupting parts 343 and 344 in front of and in the rear of the resistance part 363 are both in an on state, the resistance value of the resistance part 363 is a value corresponding to the control voltage VA1 (state in which the control voltage VA1 is selected).

On the other hand, the control voltage VA2 is applied to the resistance part 362. When the interrupting parts 351 and 352 in front of and in the rear of the resistance part 362 are both in an on state, the resistance value of the resistance part 362 is a value corresponding to the control voltage VA2 (state in which the control voltage VA2 is selected). Similarly, the control voltage VA2 is applied to the resistance part 364. When the interrupting parts 353 and 354 in front of and in the rear of the resistance part 364 are both in an on state, the resistance value of the resistance part 364 is a value corresponding to the control voltage VA2 (state in which the control voltage VA2 is selected).

For example, the magnitude of currents flowing through the control paths 381 and 383 in the state in which the control voltage VA1 is selected is different from the magnitude of currents flowing through the control paths 382 and 384 in the state in which the control voltage VA2 is selected. Due to this difference, the delay time of the delay device 311 changes between a delay time in the state in which the control voltage VA1 is selected and a delay time in the state in which the control voltage VA2 is selected.

The resistance parts 361 to 364 are, for example, a transistor such as a metal oxide semiconductor field effect transistor (MOSFET) or the like. Variations in threshold value of these transistors relatively greatly affect variations in the delay time of each delay device.

The delay device 311 includes an even number of unit circuits (two unit circuits 371 and 372 in the mode illustrated in FIG. 8) coupled in series with each other. Thus, the logic level of the reference clock CL is the same at the input part IN and the output part OUT. In addition, because a rising speed and a falling speed of edges of the reference clock CL are different from each other, the difference between both speeds may be canceled out by coupling the even number of unit circuits in series with each other.

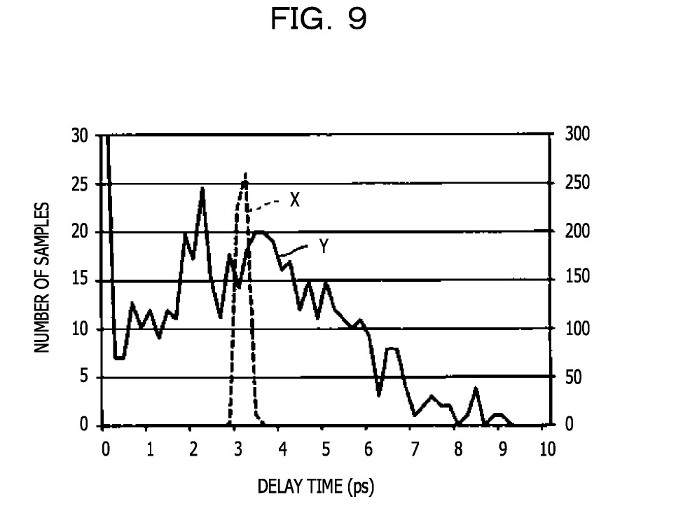

FIG. 9 is a diagram illustrating an example of variations in the delay time of 3 ps in the comparative example and the embodiment. X represents the embodiment of FIG. 5. Y represents the comparative example of FIG. 2. The number of samples represents the sample population of delay devices. In the case of Y, 3 σ of delay time variation is 6.6 ps, whereas 3 σ of delay time variation may be reduced to 0.27 ps in the case of X. Thus, delay time variation may be suppressed.

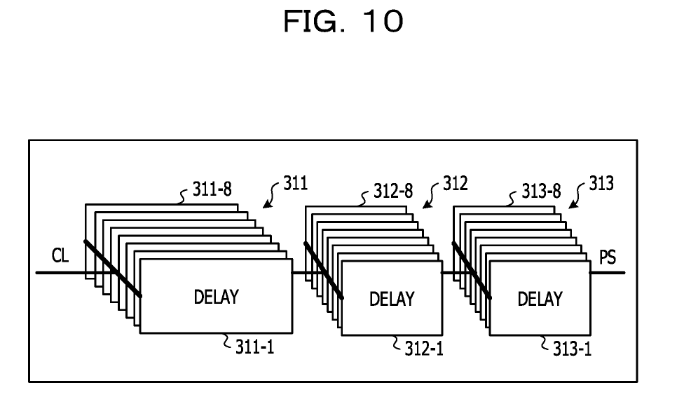

FIG. 10 illustrates an example of another configuration of delay devices. At least one of delay devices 311, 312, and 313 includes a plurality of delay circuits coupled in parallel with each other. The plurality of delay circuits have intercoupled input parts and intercoupled output parts. Each of these delay circuits, for example, has the circuit configuration illustrated in FIG. 8. Delay time variation may be further reduced by parallelizing the delay circuits.

In FIG. 10, the delay device 311 includes eight delay devices 311-1 to 311-8 coupled in parallel with each other, the delay device 312 includes eight delay devices 312-1 to 312-8 coupled in parallel with each other, and the delay device 313 includes eight delay devices 313-1 to 313-8 coupled in parallel with each other. When there are no parallel couplings, 3 σ of delay time variation is 0.27 ps. On the other hand, according to the mode of FIG. 10, 3 σ of delay time variation may be further reduced to 0.17 σ.

Pulse position modulation circuits have been described above based on embodiments. However, the present disclosure is not limited to the foregoing embodiments. Various modifications and improvements such as combination and replacement with a part or the whole of other embodiments and the like are possible within the scope of the present disclosure.

For example, the pulse position modulation circuits are not limited to usage in a radio communication system, but may also be used in a wire communication system. For example, in wire communication between circuits, a transmitter and a receiver may each include a pulse position modulation circuit.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A pulse position modulation circuit comprising:
a delay path that includes a plurality of delay devices coupled in series with each other, a clock being passed through the plurality of delay devices; and
a switching circuit that changes a time by which the clock is delayed in each of the plurality of delay devices according to input data.

2. The pulse position modulation circuit according to claim 1, wherein
the switching circuit changes a control signal that controls the time by which the clock is delayed in each of the plurality of delay devices according to the input data.

3. The pulse position modulation circuit according to claim 2, wherein
each of the plurality of delay devices includes a plurality of control paths, and
the switching circuit selects a path that controls the time by which the clock is delayed according to the control signal from the plurality of control paths according to the input data.

4. The pulse position modulation circuit according to claim 3, wherein
each of the plurality of delay devices includes a first inverter and a second inverter having an output of the first inverter as an input to the second inverter, and
the plurality of control paths are coupled between an output of the second inverter and an input of the first inverter.

5. The pulse position modulation circuit according to claim 4, wherein
each of the plurality of control paths includes an interrupting part that interrupts coupling between the output of the second inverter and the input of the first inverter according to the input data and a resistance part that has a resistance value changing according to the control signal.

6. The pulse position modulation circuit according to claim 4, wherein
each of the plurality of delay devices includes an even number of unit circuits coupled in series with each other, and
each of the even number of unit circuits includes the first inverter, the second inverter, and the plurality of control paths.

7. The pulse position modulation circuit according to claim 1, wherein
each of the plurality of delay devices includes a plurality of delay circuits coupled in parallel with each other.

8. A transmitter comprising:
a pulse position modulation circuit including a delay path that includes a plurality of delay devices coupled in series with each other, a clock being passed through the plurality of delay devices, and a switching circuit that changes a time by which the clock is delayed in each of the plurality of delay devices according to input data;
the transmitter radio-transmitting a signal based on a modulated signal output from the pulse position modulation circuit.
